(19) United States
(12) Patent Application Publication
(10) Pub. No.: US 2017/0263463 A1
(43) Pub. Date: Sep. 14, 2017

(54) METHOD FOR ETCHING SILICON SUBSTRATE USING PLASMA GAS

(71) Applicant: Industry-Academic Cooperation Foundation of Ajou University, Suwon-si, Gyeonggi-do (KR)

(72) Inventors: Chang-Koo KIM, Seoul (KR); Sung-Woon CHO, Suwon-si, Gyeonggi-do (KR); Jun-Hyun KIM, Seongnam-si, Gyeonggi-do (KR)

(73) Assignee: Industry-Academic Cooperation Foundation of Ajou University, Suwon-si, Gyeonggi-do (KR)

(21) Appl. No.: 15/529,298

(22) PCT Filed: Nov. 10, 2015
(86) PCT No.: PCT/KR2015/012037

§ 371 Date: May 24, 2017

(30) Foreign Application Priority Data
Nov. 25, 2014 (KR) 10-2014-0165011

(51) Int. Cl. H01L 21/3065; H01L 21/308

(52) U.S. Cl. CPC H01L 21/3065; H01L 21/3081

(57) ABSTRACT

There is provided a method for etching a silicon substrate, the method comprising: forming an etch mask on a silicon substrate; forming a first gas comprising a halogen-based gas, a fluorocarbon gas and oxygen; and etching the silicon substrate by generating a plasma on the silicon substrate using the first gas.

### BACKGROUND

Field of the Present Disclosure

The present disclosure relates to a method for etching a silicon substrate using a plasma gas. The present disclosure may be applied to anisotropic etching of the silicon substrate using the plasma gas.

Discussion of Related Art

Silicon is mainly used for semiconductor devices, MEMS (microelectromechanical system) devices, and optical devices, etc. The silicon may be subjected to anisotropic etching depending on the applications thereof When the silicon is used in the MEMS, the semiconductor device, or the like, a precise etching shape control is essential for improving the degree of integration. This is because the MEMS or semiconductor device may have excellent performance when the etched silicon has an anisotropic structure.

Typical conventional methods for etching the silicon to acquire a resulting anisotropic etched structure include a Bosch process and a cryogenic etching process.

The Bosch process is a method of etching the silicon to a desired depth by alternately etching and depositing the silicon. In the Bosch process, etching is first performed, then, a protective film is deposited, and then only a depth is etched away while protecting a sidewall face of the etched portion using the deposited protective film. In this way, the silicon is etched to a desired depth by repeating the deposition and etching steps. However, in the Bosch process, since the etching of the silicon itself is isotropic, the sidewall face in an etched hole is not smooth. Further, since the deposition and etching steps are repeated, the process speed is slow and the process becomes complicated.

The cryogenic etching process is an etching process while a temperature of a substrate to be etched is maintained at −100° C. or lower. In the cryogenic etching process, a plasma gas containing a mixture of SF₆ and O₂ gases is generally used. The O₂ gas reacts with the silicon substrate at a cryogenic temperature to form a sidewall face having an etching resistance. Thus, the side wall face serves as a mask during the etching to allow an anisotropic etching. However, in the cryogenic etching process, it is difficult to realize an apparatus and an environment for maintaining the temperature of the substrate at a very low temperature, and the substrate may be damaged due to thermal stress.

The prior art document directed to the anisotropic etching method of the silicon substrate is as follows: Korean patent No. 10-0265562.

### SUMMARY

This Summary is provided to introduce a selection of concepts in a simplified form that are further described below in the Detailed Description. This Summary is not intended to identify all key features or essential features of the claimed subject matter, nor is it intended to be used alone as an aid in determining the scope of the claimed subject matter.

The present disclosure is to provide a method for etching silicon in order to obtain an anisotropically etched silicon substrate which allows good performance in various applications.

In one aspect of the present disclosure, there is provided a method for etching a silicon substrate, the method comprising: forming an etch mask on a silicon substrate; forming a first gas comprising a halogen-based gas, a fluorocarbon gas and oxygen; and etching the silicon substrate by generating a plasma on the silicon substrate using the first gas.

In one embodiment, the etching is conducted at a temperature of 5° C. or higher.

In one embodiment, the halogen-based gas includes SF₆, Cl₂, and/or HBr.

In one embodiment, the fluorocarbon gas includes one or more of C₄F₆, C₄F₈, C₂F₆ and CH₂F₂.

In one embodiment, the etch mask may be made of SiO₂. The size of the etch mask may be selected to have a target resulting etched structure. In one embodiment, the size may be set to several tens of nanometers to several tens of micrometers.

In accordance with the silicon etching method of the present disclosure as described above, etching may be executed in a single step, compared to the conventional silicon etching method. Thus, the etching process is simple and the process time may be shortened.

In addition, in accordance with the silicon etching method of the present disclosure as described above, the side wall surface of the etched portion in the silicon substrate is anisotropically or vertically formed in the crystal direction of the silicon, so that it is possible to manufacture the silicon substrate having excellent reflectance. As a result, this may allow the MEMS device or semiconductor device with excellent performance.

### BRIEF DESCRIPTION OF THE DRAWINGS

The accompanying drawings, which are incorporated in and form a part of this specification and in which like numerals depict like elements, illustrate embodiments of the present disclosure and, together with the description, serve to explain the principles of the disclosure.

FIG. 1 is a flow chart illustrating a method for etching a silicon substrate according to the present disclosure.

FIG. 2 is a schematic view illustrating a mechanism of anisotropically etching the silicon by the silicon etching method according to the present example.

FIG. 3 is a photograph of the etching result of the comparative example 1.

FIG. 4 is a photograph of the etching result of the comparative example 2.

FIG. 5 is a photograph of the etching result of the comparative example 3.

FIG. 6 is a photograph of the etching result of the comparative example 4.

FIG. 7 is a photograph of the etching result of the silicon etching method of the present example conducted for 300 seconds.

FIG. 8 is a photograph of the etching result of the silicon etching method of the present example conducted for 600 seconds.

FIG. 9 is a graph illustrating comparisons between the deposition rates of a thin film on a side wall face in an etched portion in a silicon substrate when various fluorocarbon gases are used as a plasma gas.

### DETAILED DESCRIPTIONS

Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims. Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

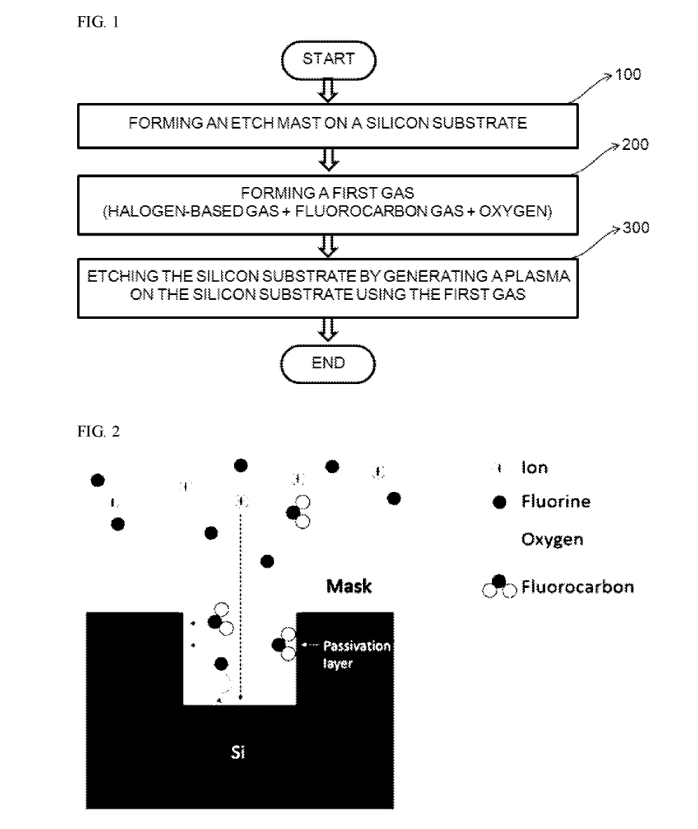

FIG. 1 is a flow chart illustrating a method for etching a silicon substrate according to the present disclosure.

Referring to FIG. 1, a method for etching a silicon substrate according to the present disclosure includes forming an etch mask on a silicon substrate 100; forming a first gas comprising a halogen-based gas, a fluorocarbon gas and oxygen 200; and etching the silicon substrate by generating a plasma on the silicon substrate using the first gas 300.

In one embodiment, the etching step 300 may be conducted at a temperature of about 5° C. or higher, more preferably about 5 to 30° C.

In one embodiment, the etch mask may be made of SiO₂. The size of the etch mask may be properly selected according to a size of a target etching area. In one embodiment, the size of the etch mask may be set to several tens of nanometers to several tens of micrometers.

In one embodiment, the halogen-based gas may be defined as a gas containing a halogen element. For example, the halogen-based gas may include one or more of SF₆, Cl₂, and HBr. In one embodiment, the halogen-based gas may preferably include SF₆ gas.

The fluorocarbon gas may be defined as a gas containing carbon and fluorine. For example, the fluorocarbon gas may include one or more of C₄F₆, C₄F₈, C₂F₆ and CH₂F₂. In one embodiment, the fluorocarbon gas may preferably include C₄F₆ gas.

Hereinafter, a present example according to the etching method of the present disclosure and comparison examples will be described.

### PRESENT EXAMPLE

TABLE 1

| | Source | Bias | | | | |
|---|---|---|---|---|---|---|
| | power | voltage | Flow rate | Pressure | Temperature | Duration |
| First gas | (W) | (−V) | (sccm) | (mTorr) | (° C.) | (s) |
| SF6, O2, C4F6 | 300 | 50 | SF6:2.5O2:1C4F6:1 | 5 | 5 | 300, 600 |

Table 1 shows types of process gases and process conditions for carrying out the silicon etching method according to the present example.

Referring to Table 1, SF₆ as the halogen-based gas, C₄F₆ as the fluorocarbon gas, and oxygen (O₂) gas were mixed and used as the first gas according to the silicon etching method of the present example. In the plasma etching step, the source power was 300 W, the bias voltage was −50 V, the pressure was 5 mTorr, and the temperature was kept at 5° C. The plasma etching time was 300 seconds and 600 seconds, respectively. The flow rate was 2.5 sccm for SF₆ as the halogen-based gas, 1 sccm for O₂, and 1 sccm for C₄F₆ as the fluorocarbon gas.

FIG. 2 is a schematic view illustrating a mechanism of anisotropically etching the silicon by the silicon etching method according to the present example.

Referring to FIG. 2, it may be confirmed that when a plasma gas of the first gas is vertically directed to the bottom surface of a trench in the silicon substrate from above the silicon substrate, the C₄F₆ and O₂ contained in the first gas react with silicon to form SiO-CFx, which is deposited as a thin film on a sidewall face of the trench. When the silicon is etched by the SF₆, the SiO-CFx thin film serves as an etch mask to prevent the sidewall face of the trench from being etched by SF₆. Since the first gas is directly and vertically incident onto the bottom surface of the trench in the silicon substrate, the formation of the thin film of the SiO-CFx on the bottom face is suppressed, and thus, the bottom face is normally etched away by SF₆ gas. Therefore, the silicon substrate may be anisotropically etched by the plasma gas of the first gas, because the SiO-CFx thin film prevents the sidewall face of the trench from being etched and the bottom surface of the trench keeps on being etched away.

### Comparison Example 1

TABLE 2

| | Source | Bias | | | | |
|---|---|---|---|---|---|---|
| | power | voltage | Flow rate | Pressure | Temperature | Duration |
| Gas | (W) | (−V) | (sccm) | (mTorr) | (° C.) | (s) |
| SF6 | 300 | 50 | 2.5 | 5 | 5 | 300 |

Table 2 shows the type of gas and process conditions for carrying out a continuous etching process of comparative example 1 only using SF₆ gas in accordance with the conventional silicon etching method.

Referring to Table 2, the comparison example 1 differs from the present example in that the process gas of the comparison example 1 only contains SF₆. That is, the process conditions such as the source power, bias voltage, flow rate, pressure, temperature, and etching time are the same as in the present example. In this connection, in the comparison example 1, the etching duration was 300 seconds.

### Comparison Example 2

TABLE 3

| | | Source | Bias | | | | |
|---|---|---|---|---|---|---|---|
| | | power | voltage | Flow rate | Pressure | Temperature | Duration |
| Steps | Gas | (W) | (−V) | (sccm) | (mTorr) | (° C.) | (s) |
| Deposition | C₄F₈ | 200 | 0 | 20 | 30 | 5 | 20 |
| Etching | SF₆ | 300 | 50 | 2.5 | 5 | 5 | 60 |

Table 3 shows types of process gases and process conditions for carrying out the Bosch process of the comparative example 2 in which the deposition and etching steps are repeatedly and alternately performed, in accordance with the conventional silicon etching method.

Referring to Table 3, in the comparison example 2, C₄F₈ gas was used in the deposition step. The deposition conditions were as follows: source power 200 W, bias voltage 0 V, flow rate of C₄F₈ gas 20 sccm, pressure 30 mTorr, temperature 5° C. The deposition was carried out for 20 seconds.

In the etching step, SF₆ gas was used as the etch gas. The etching conditions were as follows: a source power of 300 W, a bias voltage of −50 W, a flow rate of SF₆ gas of 2.5 sccm, a pressure of 5 mTorr. The etching step was performed for 60 seconds.

In the comparative example 2, the deposition step and the etching step were alternately repeated 10 times to carry out the Bosch process.

### Comparison Example 3

TABLE 4

| | Source | Bias | | | | |
|---|---|---|---|---|---|---|
| | power | voltage | Flow rate | Pressure | Temperature | Duration |
| Gas | (W) | (−V) | (sccm) | (mTorr) | (° C.) | (s) |
| SF6, O2 | 300 | 50 | SF6:2.5O2:1 | 5 | 5 | 600 |

Table 4 shows the type of the process gas and process conditions for carrying out an etching process of the comparative example 3 using a mixture of SF₆ gas and O₂ gas in accordance with the conventional silicon etching method.

Referring to Table 4, the comparison example 3 differs from the present example in that the process gas was free of C₄F₆. That is, the process conditions such as the source power, bias voltage, flow rate, pressure, temperature, and etching time are the same as in the present example. In this connection, in the comparison example 3, the etching duration was 600 seconds.

### Comparison Example 4

TABLE 5

| | Source | Bias | | | | |
|---|---|---|---|---|---|---|
| | power | voltage | Flow rate | Pressure | Temperature | Duration |
| Gas | (W) | (−V) | (sccm) | (mTorr) | (° C.) | (s) |
| SF6, C₄F6 | 300 | 50 | SF6:2.5C₄F6:1 | 5 | 5 | 600 |

Table 5 shows the type of the process gas and process conditions for carrying out an etching process of the comparative example 4 using a mixture of SF₆ gas and C₄F₆ gas in accordance with the conventional silicon etching method.

Referring to Table 5, the comparison example 4 differs from the present example in that the process gas was free of O₂. That is, the process conditions such as the source power, bias voltage, flow rate, pressure, temperature, and etching time are the same as in the present example. In this connection, in the comparison example 4, the etching duration was 600 seconds.

### Comparison Between Etching Results of Present Examples and Comparative Examples 1 to 4

FIGS. 3 to 8 are photographs of etching results of the silicon substrate according to the processes of comparative examples 1 to 4 and the present example as described above respectively.

FIG. 3 is a photograph of the etching result of the comparative example 1. Referring to FIG. 3, when the silicon substrate is continuously etched via the process of the comparative example 1 using only SF₆ gas, it may be confirmed that the silicon substrate is etched not anisotropically but isotropically. That is, the silicon substrate was etched to the same degree in all directions. As a result, the etching laterally progressed toward a portion of the silicon substrate beneath the etching mask, so that the silicon substrate was not etched in a desired pattern.

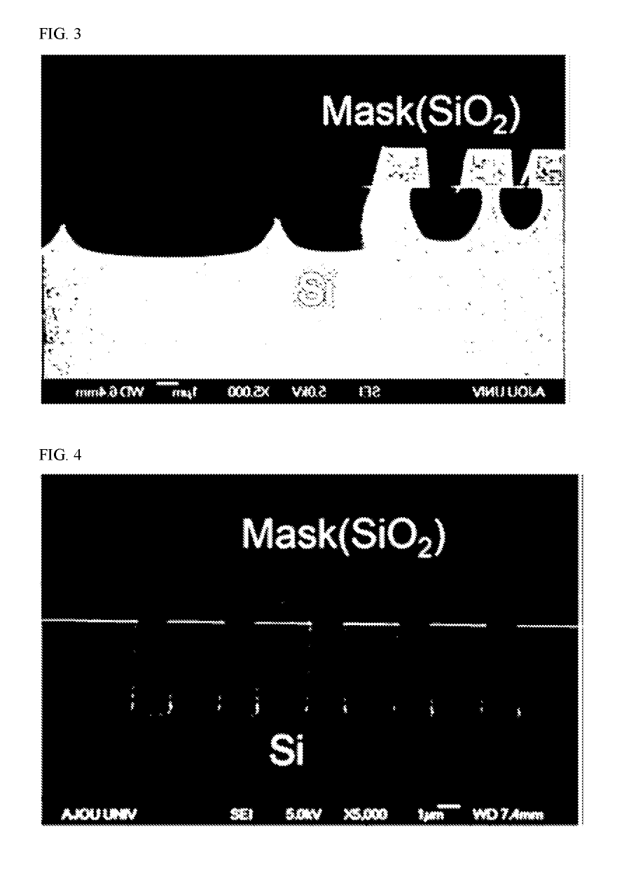

FIG. 4 is a photograph of the etching result of the comparative example 2. Referring to FIG. 4, in the case of the comparative Example 2 using the Bosch process wherein the deposition step and the etching step are alternately repeated, it may be confirmed that the silicon substrate is etched anisotropically generally. However, it may be confirmed that the sidewall face of the trench is not smooth and the corrugations or wrinkles are formed thereon. It is believed that the corrugations are formed on the sidewall surface during an interval between the deposition step and the etching step. That is, it was confirmed that the anisotropy was not completely exhibited in the comparison example 2.

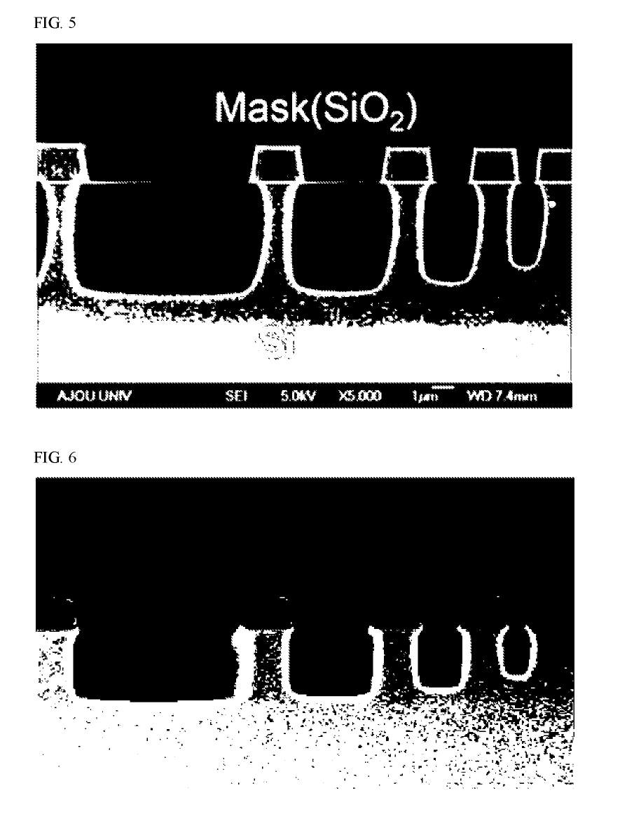

FIG. 5 is a photograph of the etching result of the comparative example 3. Referring to FIG. 5, in the comparative example 3 in which etching was performed using a mixture gas of SF₆ and O₂, it was found out that more anisotropic etching was performed compared to the comparison example 1, but a portion of the silicon substrate under the etching mask was partly etched, and, thus, the completely vertical anisotropic etching was not performed.

FIG. 6 is a photograph of the etching result of the comparative example 4. Referring to FIG. 6, in the comparative example 4 in which etching was performed using a mixed gas of SF₆ and C₄F₆, it was confirmed that etching was performed more anisotropically as compared to the comparative example 1 and comparative example 3, but the sidewall face of the trench is not completely vertical and the isotropic etching occurred slightly.

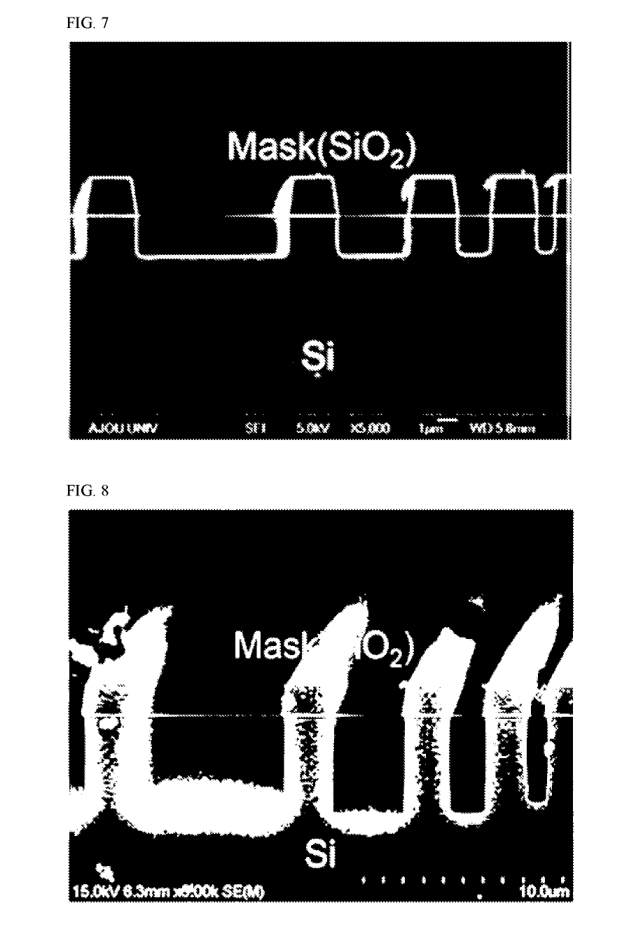

FIG. 7 is a photograph of the etching result of the silicon etching method of the present example conducted for 300 seconds. FIG. 8 is a photograph of the etching result of the silicon etching method of the present example conducted for 600 seconds.

Referring to FIGS. 7 and 8, it may be seen that in the case of performing etching using the mixture gas of SF₆, C₄F₆, and O₂, the etching was performed more anisotropically compared to the etching results of the comparative examples 1 to 4. In particular, it may be seen that, unlike the case of the comparative examples 1, 3 and 4, the sidewall face and the bottom face of the trench of the silicon substrate are perpendicular to each other. In addition, it may be confirmed that no wrinkles or corrugations as produced in the comparative example 2 are produced.

Therefore, as a result of the above comparisons, it was confirmed that the superior anisotropic etching for the silicon substrate can be performed by the present example as compared to the comparative examples 1 to 4, which are the conventional etching methods.

### Comparison Between Deposition Rates of Passivation Thin Films on Etched Side Wall

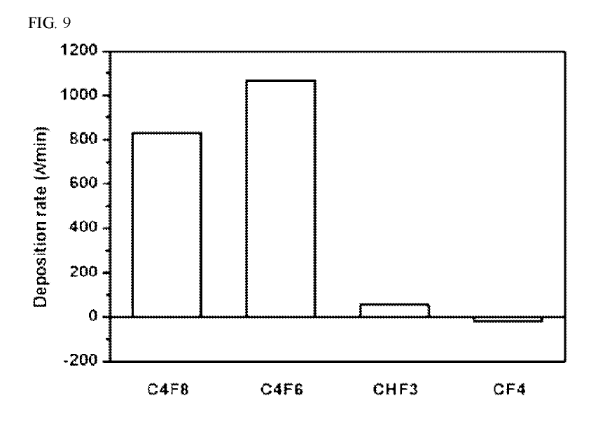

FIG. 9 is a graph illustrating comparison between the deposition rates of a thin film on a side wall face in a trench in a silicon substrate when various fluorocarbon gases are used as a plasma gas.

Referring to FIG. 9, for the comparison, as the fluorocarbon gases, C₄F₈, C₄F₆, CHF₃ and CF₄ were employed for the etching of the silicon substrate. Between C₄F₈, C₄F₆, CHF₃ and CF₄ as the fluorocarbon gases, the deposition rates at which the passivation thin film is deposited on the sidewall face of the trench, that is, the etched portion in the silicon substrate are compared with each other. The etching conditions were as follows: a source power: 250 W, a bias voltage: 0 V, a pressure: 10 mtorr, a flow rate of each process gas: 30 sccm, and a temperature: 5° C.

As a comparison result, when the substrate was subjected to the plasma treatment using the fluorocarbon gas of C₄F₈ or C₄F₆, the substrate was etched with anisotropy. However, when the substrate is plasma-treated using the gas of CHF₃ or CF₄, the substrate is etched with isotropy. As a result, in the case of using CHF₃ or CF₄, it is possible to form the passivation thin film on the trench side wall surface at a low temperature, but it is confirmed that the thin film cannot be formed on the sidewall surface of the trench of the silicon substrate at a temperature of 5° C. or more as in the present example.

These results indicate that the fluorocarbon gas having a high carbon content allows faster deposition rate than the fluorocarbon gas having a low carbon content, and, thus, has a superior ability to form the passivation thin film than the fluorocarbon gas having a low carbon content. That is, when the fluorocarbon gas of CHF₃ or CF₄ is included, the CFₓ thin film is hardly formed on the side wall surface of the trench during the plasma etching of the substrate. Thus, it is confirmed that it is difficult to expect the anisotropic etching of the silicon substrate. For the same reason, it is also considered that the fluorocarbon gas in accordance with the present disclosure preferably uses a gas having a high fluorine content, for example, C₄F₈ or C₄F₆.

It is to be understood that while the present disclosure has been particularly shown and described with reference to the exemplary embodiments thereof, the disclosure is not limited to the disclosed exemplary embodiments. On the contrary, it will be understood by those skilled in the art that various modifications may be made without departing from the spirit and scope of the present disclosure.

It is understood by those skilled in the art that various variants and alternatives may be selected in the present disclosure without departing from the spirit or scope of the present disclosure. Accordingly, it is intended that the present disclosure covers the modifications and variations when they come within the scope of the appended claims and their equivalents.

In the present specification, a reference has been made to all the device and method disclosures. In this connection, the descriptions of the device and method disclosures may be applied to each other in a supplementing manner.

The above description is not to be taken in a limiting sense, but is made merely for the purpose of describing the general principles of exemplary embodiments, and many additional embodiments of this disclosure are possible. It is understood that no limitation of the scope of the disclosure is thereby intended. The scope of the disclosure should be determined with reference to the Claims. Reference throughout this specification to “one embodiment,” “an embodiment,” or similar language means that a particular feature, structure, or characteristic that is described in connection with the embodiment is included in at least one embodiment of the present disclosure. Thus, appearances of the phrases “in one embodiment,” “in an embodiment,” and similar language throughout this specification may, but do not necessarily, all refer to the same embodiment.

What is claimed is:

1. A method for etching a silicon substrate, the method comprising:
forming an etch mask on a silicon substrate;
forming a first gas comprising a halogen-based gas, a fluorocarbon gas and oxygen; and
etching the silicon substrate by generating a plasma on the silicon substrate using the first gas.

2. The method of claim 1, wherein the etching is conducted at a temperature of 5° C. or higher.

3. The method of claim 1, wherein the halogen-based gas comprises one or more of SF₆, Cl₂, and HBr.

4. The method of claim 1, wherein the fluorocarbon gas comprises one or more of C₄F₆, C₂F₆ and CH₂F₂.
